(19) United States
(12) Patent Application Publication
(10) Pub. No.: US 2024/0312764 A1
(43) Pub. Date: Sep. 19, 2024

(54) MATCHER, SUBSTRATE PROCESSING APPARATUS, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Tsuyoshi TAKEDA, Toyama (JP); Daisuke HARA, Toyama (JP)

(21) Appl. No.: 18/436,809

(22) Filed: Feb. 8, 2024

(30) Foreign Application Priority Data
Mar. 17, 2023 (JP) 2023-042715

(51) Int. Cl. H01J 37/32; H03H 7/38

(52) U.S. Cl. CPC H01J 37/32183; H03H 7/38; H01J 2237/327

(57) ABSTRACT

There is provided a technique capable of sufficiently stabilizing a generation of a plasma by avoiding an improper impedance matching. There is provided a technique that includes: an input structure configured to receive a high frequency power, an output structure configured to output the high frequency power; a matching structure containing a variable inductor with a variable inductance; and a variable inductance regulator capable of varying the inductance of the variable inductor.

### CROSS REFERENCE TO RELATED APPLICATIONS

This non-provisional U.S. patent application is based on and claims priority under 35 U.S.C. § 119 of Japanese Patent Application No. 2023-042715, filed on Mar. 17, 2023, in the Japanese Patent Office, the entire contents of which are hereby incorporated by reference.

### TECHNICAL FIELD

The present disclosure relates to a matcher, a substrate processing apparatus, a method of manufacturing a semiconductor device and a non-transitory computer-readable recording medium.

### BACKGROUND

As a part of a manufacturing process of a semiconductor device, a substrate processing may be performed. According to the substrate processing, various films such as an insulating film, a semiconductor film and a conductor film may be formed on a substrate by loading (transferring) the substrate into a process chamber of a substrate processing apparatus and supplying a source gas and a reactive gas into the process chamber, or may be removed from the substrate.

In a mass-produced device in which a fine pattern is formed, the substrate processing may be preferably performed at a lower temperature. In such a case, in order to prevent a surface reaction during the substrate processing (wafer processing) from reaching a rate-limiting state, it is preferable to supply a much larger amount of the reactive gas (which is activated) than usual.

For example, it is common to perform the substrate processing by using a plasma generated by a high frequency power supply. However, due to differences in elements in a matcher, characteristics of the plasma may vary due to an improper impedance matching. Thereby, an amount of active species generated by the plasma may also vary.

### SUMMARY

According to the present disclosure, there is provided a technique capable of stabilizing a generation of a plasma by avoiding an improper impedance matching described above.

According to an aspect of the present disclosure, there is provided a technique that includes: an input structure configured to receive a high frequency power; an output structure configured to output the high frequency power; a matching structure containing a variable inductor with a variable inductance; and a variable inductance regulator capable of varying the inductance of the variable inductor.

### BRIEF DESCRIPTION OF THE DRAWINGS

FIG. 1 is a diagram schematically illustrating a vertical cross-section of a vertical type process furnace of a substrate processing apparatus preferably used in a first embodiment of the present disclosure.

FIG. 2 is a diagram schematically illustrating a horizontal cross-section taken along a line A-A of the substrate processing apparatus shown in FIG. 1.

FIG. 3 is a diagram schematically illustrating an example of an equivalent electric circuit of a matcher in the first embodiment of the present disclosure.

FIG. 4 is a diagram schematically illustrating a modified example of the equivalent electric circuit of the matcher in the first embodiment of the present disclosure.

FIG. 5 is a diagram schematically illustrating a configuration of a movable connector and a variable inductance regulator shown in FIG. 4.

FIG. 6 is a block diagram schematically illustrating an exemplary configuration of a controller and related components of the substrate processing apparatus shown in FIG. 1.

FIG. 7 is a flow chart schematically illustrating an example of a substrate processing performed by using the substrate processing apparatus shown in FIG. 1.

FIG. 8 is a diagram schematically illustrating a horizontal cross-section of a vertical type process furnace of a substrate processing apparatus preferably used in a second embodiment of the present disclosure.

### DETAILED DESCRIPTION

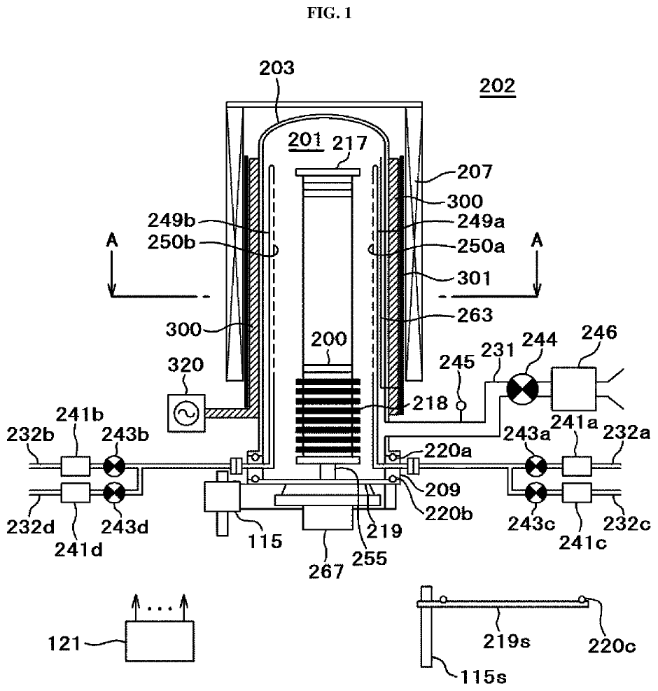

Hereinafter, one or more embodiments (also simply referred to as “embodiments”) of the technique of the present disclosure will be described in detail mainly with reference to FIGS. 1 through 5. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### First Embodiment

### (1) Configuration of Substrate Processing Apparatus

### <Heater>

As shown in FIG. 1, a vertical type substrate processing apparatus (hereinafter, also simply referred to as a “substrate processing apparatus”) according to the present embodiment includes a process furnace 202 such as a vertical type process furnace. The process furnace 202 includes a heater 207 serving as a heating apparatus (which is a heating structure or a heating system). The heater 207 is of a cylindrical shape, and is vertically installed while being supported by a support plate (not shown). The heater 207 also functions as an activator (also referred to as an “exciter”) capable of activating (or exciting) a gas by a heat.

### <Process Chamber>

An electrode fixture 301 described later is provided in an inner side of the heater 207, and an electrode 300 of a plasma generator (which is a plasma generating structure) described later is provided in an inner side of the electrode fixture 301. Further, a reaction tube 203 is provided in an inner side of the electrode 300 to be aligned in a manner concentric with the heater 207. For example, the reaction tube 203 is made of a heat resistant material such as quartz (SiO₂) and silicon carbide (SiC). The reaction tube 203 is of a cylindrical shape with a closed upper end and an open lower end. A manifold 209 is provided under the reaction tube 203 to be aligned in a manner concentric with the reaction tube 203. For example, the manifold 209 is made of a metal material such as stainless steel (SUS). The manifold 209 is of a cylindrical shape with open upper and lower ends. An upper end portion of the manifold 209 is engaged with a lower end portion of the reaction tube 203 so as to support the reaction tube 203. An O-ring 220a serving as a seal is provided between the manifold 209 and the reaction tube 203. The reaction tube 203 is installed vertically while the manifold 209 is being supported by a heater base (not shown). A process vessel (also referred to as a “reaction vessel”) is constituted mainly by the reaction tube 203 and the manifold 209. A process chamber 201 is provided in a hollow cylindrical portion of the process vessel. The process chamber 201 is configured to accommodate a plurality of wafers including a wafer 200 serving as a substrate. The wafer 200 is processed in the process chamber 201. Hereinafter, the plurality of wafers including the wafer 200 may also be simply referred to as “wafers 200”. However, the process vessel is not limited to the configuration described above. For example, the reaction tube 203 alone may also be referred to as the “process vessel”.

### <Gas Supplier>

Nozzles 249a and 249b are provided in the process chamber 201 so as to penetrate a side wall of the manifold 209. The nozzles 249a and 249b serve as a first supplier (which is a first supply structure) and a second supplier (which is a second supply structure), respectively. The nozzles 249a and 249b may also be referred to as a first nozzle and a second nozzle, respectively. For example, each of the nozzles 249a and 249b is made of a heat resistant material such as quartz and SiC. Gas supply pipes 232a and 232b are connected to the nozzles 249a and 249b, respectively. For example, as described above, two nozzles 249a and 249b and two gas supply pipes 232a and 232b are provided at the process vessel such that a plurality types of gases can be supplied into the process chamber 201 via the nozzles 249a and 249b and the gas supply pipes 232a and 232b. Further, when the reaction tube 203 alone constitutes the process vessel, the nozzles 249a and 249b may be provided in the process chamber 201 so as to penetrate a side wall of the reaction tube 203.

Mass flow controllers (also simply referred to as “MFCs”) 241a and 241b serving as flow rate controllers (flow rate control structures) and valves 243a and 243b serving as opening/closing valves are sequentially installed at the gas supply pipes 232a and 232b, respectively, in this order from upstream sides to downstream sides of the gas supply pipes 232a and 232b in a gas flow direction. Gas supply pipes 232c and 232d through which an inert gas is supplied are connected to the gas supply pipes 232a and 232b, respectively, at a downstream side of the valve 243a of the gas supply pipe 232a and a downstream side of the valve 243b of the gas supply pipe 232b. MFCs 241c and 241d and valves 243c and 243d are sequentially installed at the gas supply pipes 232c and 232d, respectively, in this order from upstream sides to downstream sides of the gas supply pipes 232c and 232d in the gas flow direction.

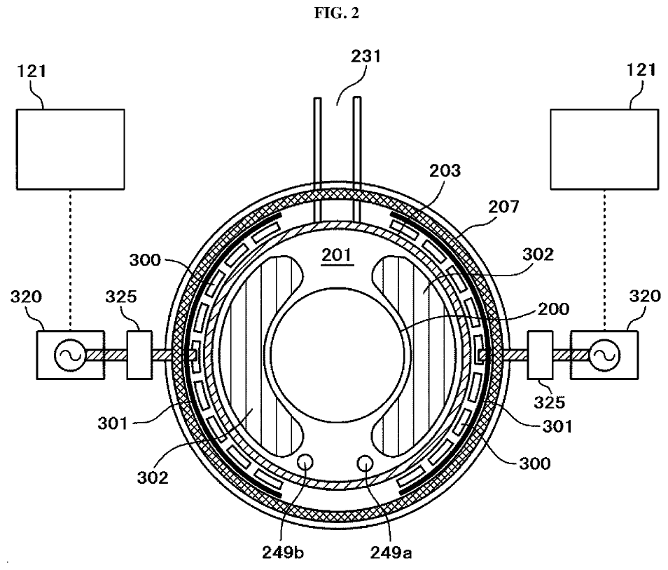

As shown in FIGS. 1 and 2, each of the nozzles 249a and 249b is installed in an annular space provided between an inner wall of the reaction tube 203 and the wafers 200 when viewed from above, and extends upward from a lower portion toward an upper portion of the reaction tube 203 along the inner wall of the reaction tube 203 (that is, extends upward along a stacking direction of the wafers 200). That is, the nozzles 249a and 249b are provided beside edges (peripheries) of the wafers 200 loaded (transferred) into the process chamber 201, and are provided perpendicular to surfaces (flat surfaces) of the wafers 200. A plurality of gas supply holes 250a and a plurality of gas supply holes 250b are provided at side surfaces of the nozzles 249a and 249b, respectively. Gases can be supplied through the gas supply holes 250a and the gas supply holes 250b, respectively. The gas supply holes 250a and the gas supply holes 250b are open toward a center of the reaction tube 203, and are configured such that the gases are supplied toward the wafers 200 through the gas supply holes 250a and the gas supply holes 250b. The gas supply holes 250a and the gas supply holes 250b are provided from the lower portion toward the upper portion of the reaction tube 203.

According to the present embodiment, the gases such as a source gas and a reactive gas are respectively supplied through the nozzles 249a and 249b, which are provided in a vertically elongated annular space (that is, a cylindrical space) when viewed from above defined by an inner surface of the side wall (that is, the inner wall) of the reaction tube 203 and the edges (peripheries) of the wafers 200 arranged in the reaction tube 203. Then, the gases are respectively ejected into the reaction tube 203 in the vicinity of the wafers 200 first through the gas supply holes 250a and the gas supply holes 250b of the nozzles 249a and 249b. Thereafter, each of the gases ejected into the reaction tube 203 mainly flows parallel to the surfaces of the wafers 200, that is, in a horizontal direction. Thereby, it is possible to uniformly supply the gases to each of the wafers 200, and it is also possible to improve a thickness uniformity of a film formed on each of the wafers 200. After flowing over the surfaces of the wafers 200, the gas (for example, a residual gas remaining after the reaction) flows toward an exhaust port, that is, toward an exhaust pipe 231 described later. However, a flow direction of the residual gas may be determined appropriately depending on a location of the exhaust port, and is not limited to the vertical direction.

A source material (that is, the source gas) is supplied into the process chamber 201 through the gas supply pipe 232a provided with the MFC 241a and the valve 243a and the nozzle 249a.

A reactant (that is, the reactive gas) is supplied into the process chamber 201 through the gas supply pipe 232b provided with the MFC 241b and the valve 243b and the nozzle 249b.

The inert gas is supplied into the process chamber 201 through the gas supply pipes 232c and 232d provided with the MFCs 241c and 241d and the valves 243c and 243d, respectively, and the nozzles 249a and 249b.

For example, a source gas supplier (which is a source gas supply structure or a source gas supply system) serving as a first gas supplier (which is a first gas supply structure or a first gas supply system) is constituted mainly by the gas supply pipe 232a, the MFC 241a and the valve 243a. The source gas supplier may also be referred to as a source material supplier (which is a source material supply structure or a source material supply system). A reactive gas supplier (which is a reactive gas supply structure or a reactive gas supply system) serving as a second gas supplier (which is a second gas supply structure or a second gas supply system) is constituted mainly by the gas supply pipe 232b, the MFC 241b and the valve 243b. The reactive gas supplier may also be referred to as a reactant supplier (which is a reactant supply structure or a reactant supply system). An inert gas supplier (which is an inert gas supply structure or an inert gas supply system) is constituted mainly by the gas supply pipes 232c and 232d, the MFCs 241c and 241d and the valves 243c and 243d. The source gas supplier, the reactive gas supplier and the inert gas supplier may be collectively referred to as a gas supplier (which is a gas supply structure or a gas supply system).

### <Substrate Support>

As shown in FIG. 1, a boat 217 (which is a substrate support or a substrate retainer) is configured to accommodate (or support) the wafers 200 (for example, 25 to 200 wafers) along a vertical direction while the wafers 200 are horizontally oriented with their centers aligned with one another with a predetermined interval therebetween in a multistage manner. For example, the boat 217 is made of a heat resistant material such as quartz and SiC. A plurality of heat insulating plates 218 horizontally oriented are provided under the boat 217 in a multistage manner. For example, each of the heat insulating plates 218 is made of a heat resistant material such as quartz and SiC. With such a configuration, the heat insulating plates 218 suppress a transmission of the heat from the heater 207 to a seal cap 219 described later. However, the present embodiment is not limited thereto. For example, instead of the heat insulating plates 218, a heat insulating cylinder (not shown) such as a cylinder made of a heat resistant material such as quartz and SiC may be provided under the boat 217.

### <Plasma Generator>

Subsequently, the plasma generator will be described with reference to FIGS. 1 to 5.

The electrode 300 for generating a plasma is provided outside the reaction tube 203, that is, outside the process vessel (process chamber 201). The electrode 300 is configured such that, by applying an electric power to the electrode 300, the gas inside the reaction tube 203 (that is, inside the process vessel (process chamber 201)) can be plasmatized and excited, that is, the gas can be excited into a plasma state. For example, by exciting the gas into the plasma state by simply applying the electric power to the electrode 300, a capacitively coupled plasma (abbreviated as CCP) serving as the plasma is generated inside the reaction tube 203, that is, inside the process vessel (process chamber 201).

Specifically, as shown in FIG. 2, the electrode 300 and the electrode fixture 301 configured to fix the electrode 300 are arranged between the heater 207 and the reaction tube 203. As described above, the electrode fixture 301 is provided in the inner side of the heater 207, and the electrode 300 is provided in the inner side of the electrode fixture 301. Further, the reaction tube 203 is provided in the inner side of the electrode 300.

In addition, as shown in FIGS. 1 and 2, each of the electrode 300 and the electrode fixture 301 is installed in an annular space provided between an inner wall of the heater 207 and an outer wall of the reaction tube 203 when viewed from above, and extends upward from the lower portion toward the upper portion of the reaction tube 203 along the outer wall of the reaction tube 203 (that is, extends upward along an arrangement direction of the wafers 200). The electrode 300 is provided in parallel to the nozzles 249a and 249b. The electrode 300 and the electrode fixture 301 are arranged to be aligned in a manner concentric with the reaction tube 203 and the heater 207, and are not to be in contact with the heater 207 when viewed from above. For example, the electrode fixture 301 is made of an insulating material (insulator), and is provided so as to cover at least a part of the electrode 300 and the reaction tube 203. Therefore, the electrode fixture 301 may also be referred to as a “cover” (which is a quartz cover, an insulating wall, or an insulating plate) or a “cover with an arc-shaped cross-section” (which is a body with an arc-shaped cross-section or a wall with an arc-shaped cross-section).

As shown in FIG. 2, a plurality of electrodes including the electrode 300 are provided. Hereinafter, the plurality of electrodes including the electrode 300 may also be simply referred to as “electrodes 300”. The electrodes 300 are fixed and installed on an inner wall of the electrode fixture 301. More specifically, a plurality of protrusions (which are hooks) (not shown) on which the electrodes 300 can be hooked are provided on a surface of the inner wall of the electrode fixture 301. Further, a plurality of openings (not shown) which are through-holes through which the protrusions can be inserted are provided at the electrodes 300. The electrodes 300 can be fixed to the electrode fixture 301 by hooking the electrodes 300 on the protrusions provided on the surface of the inner wall of the electrode fixture 301 through the openings. Preferably, two openings are provided for each of the electrodes 300 such that each of the electrodes 300 can be hooked at and fixed by the two protrusions. That is, each of the electrodes 300 may be fixed in two locations. For example, as shown in FIG. 2, there are provided a pair of structures each of which comprises nine electrodes 300 fixed to the electrode fixture 301. That is, two electrode fixtures 301 are provided, and nine electrodes 300 are fixed to each of the two electrode fixtures 301.

In the present embodiment, the electrode fixture 301 and the electrodes 300 may also be collectively referred to as an “electrode configuration”. The electrode configuration is preferably arranged at a location that can avoid a contact with the nozzles 249a and 249b and the exhaust pipe 231, as shown in FIG. 2. FIG. 2 shows an example in which two electrode configurations are arranged to face each other via centers of the wafers 200 (that is, the center of the reaction tube 203) interposed therebetween while avoiding the contact with the nozzles 249a and 249b and the exhaust pipe 231. In the example shown in FIG. 2, the two electrode configurations are arranged line-symmetrically, when viewed from above, with respect to a straight line serving as an axis of symmetry (that is, the two electrode configurations are arranged symmetrically with each other). By arranging the electrode configurations as described above, it is possible to arrange the nozzles 249a and 249b, a temperature sensor 263 described later and the exhaust pipe 231 outside a plasma generation region in the process chamber 201. Thereby, it is possible to suppress a plasma damage to components such as the nozzles 249a and 249b, the temperature sensor 263 and the exhaust pipe 231, a wear and tear of the components and a generation of particles from the components. In the present specification, unless they need to be distinguished separately, the electrode configuration will be described as the electrodes 300.

For example, a plasma (active species) 302 is generated in the reaction tube 203 by inputting a high frequency power of 25 MHz or more and 35 MHz or less (more specifically, a frequency of 27.12 MHz) to the electrode 300 from a high frequency power supply 320 via a matcher 325. By using the plasma 302 generated in such a manner described above, it is possible to supply the plasma 302 for a substrate processing described later to the surfaces of the wafers 200 from the peripheries of the wafers 200. The high frequency power supply 320 is configured to supply the high frequency power to the electrode 300.

The plasma generator (which is a plasma activator or a plasma exciter) capable of activating (or exciting) the gas into the plasma state is constituted mainly by the electrodes 300. The plasma generator may further include the electrode fixture 301, the matcher 325 and the high frequency power supply (RF power supply) 320. The matcher 325 is interposed between the high frequency power supply 320 configured to output a high frequency power and the plasma generator. Further, as shown in FIG. 2, the vertical substrate processing apparatus is provided with a plurality of high frequency power supplies including the high frequency power supply 320 and a plurality of plasma generators including the plasma generator. In addition, a plurality of matchers including the matcher 325 are provided between the plurality of high frequency power supplies including the high frequency power supply 320 and the plurality of plasma generators, respectively.

Preferably, a thickness of the electrode 300 is set to 0.1 mm or more and 1 mm or less and a width of the electrode 300 is set to 5 mm or more and 30 mm or less such that a strength of the electrode 300 is sufficient and an efficiency of heating the wafers 200 by a heat source such as the heater 207 is not significantly lowered. Further, it is preferable that the electrode 300 is of a bending structure serving as a deformation suppressing structure (which prevents a deformation due to the heating by the heater 207). In such a case, since the electrode 300 is arranged between the reaction tube 203 and the heater 207, it is preferable that a bending angle of the bending structure is set to 90° to 175° by considering space restrictions. A cover film may be formed on a surface of the electrode 300 by a thermal oxidation, and a thermal stress may cause the cover film to peel off and to generate the particles. Therefore, it is preferable not to bend the bending structure too much.

### <Matcher>

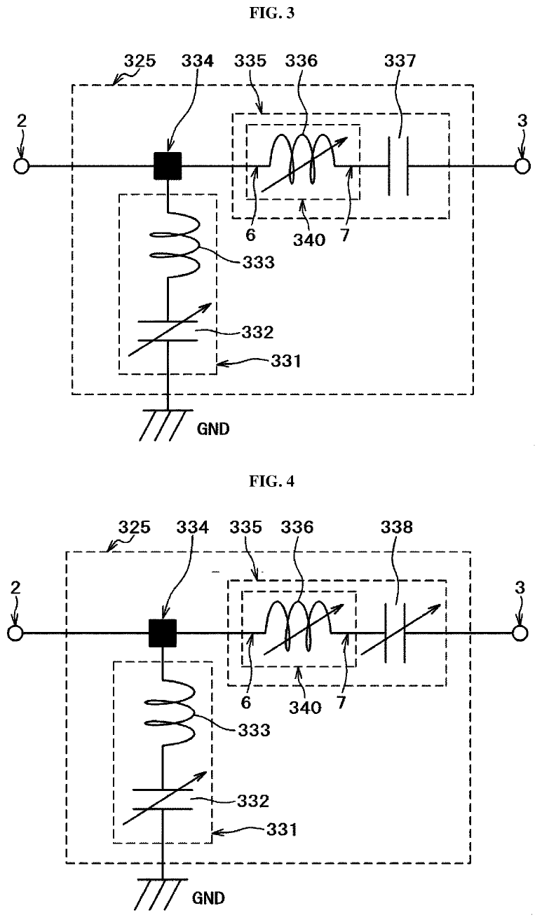

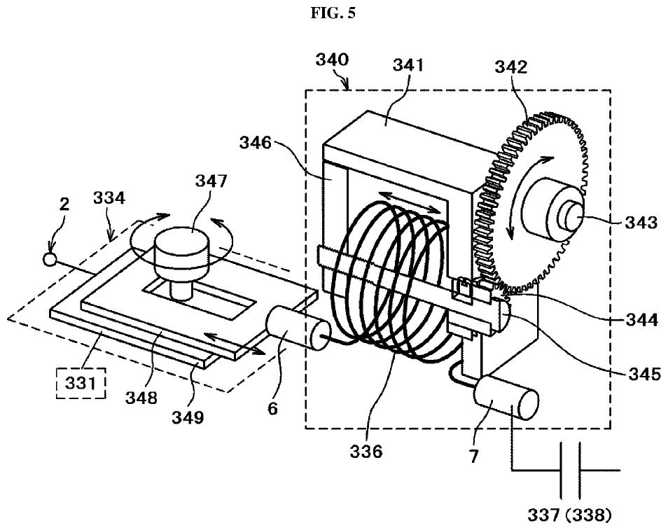

As shown in FIGS. 3 and 4, the matcher 325 includes: a first matching structure (also referred to as a “load matching structure”) 331 connected in parallel to a line (wiring) extending from an input (also referred to as an “input terminal”) 2 to an output (also referred to as an “output terminal”) 3; a second matching structure (also referred to as a “phase matching structure”) 335 connected in series to the line (wiring) extending from the input 2 to the output 3; and a movable connector 334. The input 2 may be rephrased as an input structure configured to receive the high frequency power. The output 3 can be rephrased as an output structure configured to output the high frequency power. Both the first matching structure 331 and the second matching structure 335 are connected to the movable connector 334. The movable connector 334 is also connected to the input terminal 2 on an input side. The first matching structure 331 is also connected to a ground (GND). The second matching structure 335 is also connected to the output terminal 3 on an output side. In other words, the matcher 325 includes: the input 2; the output 3; the movable connector 334 connected to the input 2; the first matching structure 331 connected between the movable connector 334 and the ground (GND); and the second matching structure 335 connected between the movable connector 334 and the output 3. The output 3 serving as an output structure is provided in the process chamber 201 in which the wafer (substrate) 200 is processed, and is connected to the electrode 300 provided in the plasma generator configured to generate the plasma.

The first matching structure 331 is constructed by connecting in series a variable capacitor (load variable capacitor) 332 with a variable capacitance and an inductor (load inductor) 333 with a fixed inductance, between the movable connector 334 and the ground (GND). The second matching structure 335 is constructed by connecting in series a variable inductor (phase variable inductor) 336 with a variable inductance and a capacitor (phase capacitor) 337 with a fixed capacitance (see FIG. 3) or a variable capacitor (phase variable capacitor) 338 with a variable capacitance (see FIG. 4), between the movable connector 334 and the output 3. That is, the second matching structure 335 is configured to include the capacitor 337 or the variable capacitor 338.

The variable inductor 336 is arranged in a variable inductance regulator 340 shown in FIG. 5, which will be described later, and is configured such that an inductance thereof can be changed (adjusted). That is, the variable inductor 336 is constituted by a coil, and is configured such that the inductance thereof can be variable by varying a pitch of the coil. Further, each of the variable capacitor 332 and the variable capacitor 338 includes a variable regulator (not shown), and is configured such that the capacitance thereof can be changed (adjusted).

The capacitance of each of the capacitors 332, 337 and 338, the inductance of each of the inductors 333 and 336 and a frequency of the high frequency power supply 320 are appropriately selected and adjusted. Thereby, it is possible to simultaneously perform an impedance matching between an input impedance of the matcher 325 and an output impedance of the high frequency power supply 320 and between an output impedance of the matcher 325 and a load impedance of the electrode 300 and the plasma 302 connected on the output 3. During the impedance matching, the high frequency power supply 320 can apply the electric power to the electrode 300 and the plasma 302 with almost no high frequency power (which is output from the high frequency power supply 320) being reflected on the way.

Specifically, in a circuit of the matcher 325 shown in FIG. 3, the capacitance of the variable capacitor 332 is adjusted such that a resistance component of the output impedance of the matcher 325 matches a resistance component of the load impedance, and the frequency of the high frequency power supply 320 is adjusted such that a reactance component of the output impedance of the matcher 325 matches a reactance component of the load impedance with its polarity reversed. In addition, in a circuit of the matcher 325 shown in FIG. 4, the capacitance of the variable capacitor 332 is adjusted such that the resistance component of the output impedance of the matcher 325 matches the resistance component of the load impedance, and the frequency of the high frequency power supply 320 is adjusted or the capacitance of the variable capacitor 338 is adjusted such that the reactance component of the output impedance of the matcher 325 matches the reactance component of the load impedance with its polarity reversed.

In the present embodiment, the inductance of the variable inductor 336 is adjusted in advance in order to shift an impedance matching range, and the inductance thereof is not adjusted simultaneously with an output of the high frequency power from the high frequency power supply 320. As shown in FIG. 2, when a plurality of high frequency power supplies including the high frequency power supply 320 are used, the above-mentioned adjustment is performed in order to prevent an improper impedance matching in each matcher 325 due to interferences with each other. Thereby, it is possible to intentionally make their impedance matching positions, particularly their impedance matching frequencies, be deviated from each other. Hereinafter, the plurality of high frequency power supplies including the high frequency power supply 320 may also be simply referred to as “high frequency power supplies 320”. Furthermore, it is possible to match impedance matching positions, particularly impedance matching frequencies between a plurality of semiconductor manufacturing apparatuses. Thereby, it is possible to stabilize a generation of the plasma by avoiding the improper impedance matching. Therefore, it is possible to manufacture a semiconductor device by performing a stable substrate processing by using a substrate processing apparatus capable of stably generating the plasma. As a result, it is possible to improve a yield of the semiconductor device and a quality of the semiconductor device.

For example, the first matching structure 331 may include the variable inductance regulator 340 in the inductor 333, or the inductor 333 itself may be eliminated.

### <Variable Inductance Regulator>

The variable inductance regulator 340 shown in FIG. 5 includes a housing 341, a large gear 342, a fixed shaft 343, a small gear 344, a rotating shaft 345 and a push plate 346. The housing 341 is of a canopy shape, and an outer surface of the push plate 346 is of the same shape as an inner side of the housing 341. The housing 341 and the push plate 346 are configured such that an inner surface of the housing 341 and the outer surface of the push plate 346 are in contact with each other and the push plate 346 can move linearly inside the housing 341. The large gear 342 and the small gear 344 have tooth profile shape with the same pitch interval, and are configured such that they mesh with each other. The rotating shaft 345 comprises a threaded shape over a half or more of its length, and the push plate (also simply referred to as a “plate”) 346 comprises a threaded hole shape, and both are connected by threaded surfaces with the same pitch interval. The large gear 342 is configured to be capable of being rotated around the fixed shaft 343 fixed to the housing 341. The large gear 342 can be rotated by an external force, for example, by a hand force, and a rotational force of the large gear 342 is transmitted to the small gear 344 that is in contact with a gear surface, and thereby the rotating shaft 345 fixed to the small gear 344 is rotated. The rotating shaft 345 is introduced into an inside of the housing 341 through a side surface of the housing 341. The rotating shaft 345 is configured to be capable of linearly moving the push plate 346 in contact with a screw hole surface in a front or rear direction inside the housing 341 while being rotated together with the small gear 344. Thereby, it is possible to expand or contract the variable inductor 336 of a coil shape (also simply referred to as a “coil”). That is, by moving the push plate 346 linearly in the front or rear direction inside the housing 341, it is possible to shorten or lengthen a distance (interval or gap) between parts of the coil constituting the variable inductor 336 in the front or rear direction. That is, by varying the pitch of the coil, the variable inductance regulator 340 can vary the inductance. Thereby, the inductance of the variable inductor 336 can be changed. Further, as shown in FIGS. 3, 4 and 5, the variable inductor 336 includes a first connector 6 and a second connector 7. The first connector 6 is connected to a movable connecting plate 348 of the movable connector 334, which will be described later. Further, the second connector 7 is connected to the capacitors 337 and 338. In addition, in order to easily apply the external force, a front part of the large gear 342 may protrude from a cutout portion of the housing of the matcher 325.

In other words, the variable inductance regulator 340 includes the housing 341 serving as a fixture configured to fix the coil of the variable inductor 336 and the push plate 346 (of a plate shape) serving as a mover configured to vary (change) the pitch of the coil. The push plate 346 serving as the mover is configured to be movable by the large gear 342, the fixed shaft 343, the small gear 344 and the rotating shaft 345, which serve as a rotation structure. The rotation structure includes the rotating shaft 345 configured to move the push plate 346, the small gear 344 serving as a first gear configured to rotate the rotating shaft 345 and the large gear 342 serving as a second gear configured to rotate the small gear 344 serving as the first gear.

### <Movable Connector>

The movable connector 334 shown in FIG. 5 is constituted by a connecting screw 347, the movable connecting plate 348 and a fixed connecting plate 349. The first connector 6 of the variable inductor 336 is connected to the movable connecting plate 348, and the first matching structure 331 and the input terminal 2 on the input side are connected to the fixed connecting plate 349. The connecting screw 347 is connected to the fixed connecting plate 349 through threaded surfaces with the same pitch such that the movable connecting plate 348 can be moved depending on a tightening amount of the connecting screw 347. That is, by loosening the connecting screw 347, the movable connecting plate 348 can be moved linearly in accordance with an amount of expansion and contraction of the variable inductor 336 by the variable inductance regulator 340 described above. By tightening the connecting screw 347, the movable connecting plate 348 and the fixed connecting plate 349 are connected, and the variable inductor 336 is electrically connected. In order to fix the inductance of the variable inductor 336 at a certain value in a manner described above, it is preferable to maximize the tightening amount of the connecting screw 347 such that the movable connecting plate 348 is interposed between a head of the connecting screw 347 and the fixed connecting plate 349. In addition, the movable connector 334 may be used between the variable inductor 336 and the capacitor 337 or between the variable inductor 336 and the variable capacitor 338. In other words, the variable inductor 336 is connected to the movable connector 334 and further connected to the input 2 via the movable connector 334. The movable connector 334 is connected to the first matching structure 331 serving as the load matching structure. The movable connector 334 includes: the movable connecting plate 348 serving as a movable structure connected to the variable inductor 336; and the fixed connecting plate 349 serving as a fixed structure of fixing the movable connecting plate 348 serving as the movable structure. The movable connector 334 further includes the connecting screw 347 configured to fix the movable connecting plate 348 serving as the movable structure to the fixed connecting plate 349. The variable inductor 336 is connected to the movable connecting plate 348 serving as the movable structure, and is electrically connected by fixing the movable connecting plate 348 serving as the movable structure to the fixed connecting plate 349 serving as the fixed structure with the connecting screw 347.

In the present embodiment, an inner pressure of the furnace (that is, the process furnace 202) when the substrate processing is performed may be preferably controlled within a range of 10 Pa or more and 300 Pa or less. When the inner pressure of the furnace is lower than 10 Pa, a mean free path of gas molecules becomes longer than the Debye length of the plasma, and the plasma directly hitting a wall of the furnace becomes noticeable. As a result, it is difficult to suppress the generation of the particles. Further, when the inner pressure of the furnace is higher than 300 Pa, an efficiency of generating the plasma is saturated so that an amount of the plasma generated does not change even when the reactive gas is supplied. Thereby, the reactive gas may be wasted. In addition, since the mean free path of the gas molecules is shortened, a transport efficiency of the active species of the plasma to the wafers 200 may deteriorate.

In order to obtain a high substrate processing capability at a substrate temperature of 500° C. or less, it is preferable that the electrode fixture 301 is of a substantially arc shape with a central angle of 30° or more and 240° or less. Further, in order to avoid the generation of the particles, it is preferable that the electrode fixture 301 is arranged to avoid a contact with the exhaust pipe 231 serving as the exhaust port and the nozzles 249a and 249b. In other words, the electrode fixture 301 is arranged on the outer periphery of the reaction tube 203 other than locations where the nozzles 249a and 249b serving as a part of the gas supplier and the exhaust pipe 231 serving as a part of an exhauster described later are installed in the reaction tube 203. According to the present embodiment, for example, two electrode fixtures 301 with a central angle of 110° are installed symmetrically.

### <Exhauster>

As shown in FIG. 1, the exhaust pipe 231 through which an inner atmosphere of the process chamber 201 is exhausted is provided at the reaction tube 203. A vacuum pump 246 serving as a vacuum exhaust apparatus is connected to the exhaust pipe 231 through a pressure sensor 245 and an APC (Automatic Pressure Controller) valve 244. The pressure sensor 245 serves as a pressure detector (which is a pressure detection structure) to detect an inner pressure of the process chamber 201, and the APC valve 244 serves as an exhaust valve (which is a pressure regulator). With the vacuum pump 246 in operation, the APC valve 244 may be opened or closed to perform a vacuum exhaust of the process chamber 201 or stop the vacuum exhaust. Further, with the vacuum pump 246 in operation, an opening degree of the APC valve 244 may be adjusted based on pressure information detected by the pressure sensor 245, in order to control (or adjust) the inner pressure of the process chamber 201. The exhauster (which is an exhaust structure or an exhaust system) is constituted mainly by the exhaust pipe 231, the APC valve 244 and the pressure sensor 245. The exhauster may further include the vacuum pump 246. However, the present embodiment is not limited to an example in which the exhaust pipe 231 is provided at the reaction tube 203. For example, similar to the nozzles 249a and 249b, the exhaust pipe 231 may be provided at the manifold 209 instead of the reaction tube 203.

### <Peripheral Components>

The seal cap 219 serving as a furnace opening lid capable of airtightly scaling (or closing) a lower end opening of the manifold 209 is provided under the manifold 209. The seal cap 219 is in contact with the lower end of the manifold 209 from thereunder. For example, the seal cap 219 is made of a metal material such as SUS, and is of a disk shape. An O-ring 220b serving as a seal is provided on an upper surface of the seal cap 219 so as to be in contact with the lower end of the manifold 209.

A rotator 267 capable of rotating the boat 217 is provided at the seal cap 219 in a manner opposite to the process chamber 201. A rotating shaft 255 of the rotator 267 is connected to the boat 217 through the seal cap 219. As the rotator 267 rotates the boat 217, the wafers 200 are rotated. The seal cap 219 may be elevated or lowered in the vertical direction by a boat elevator 115 serving as an elevating structure vertically provided outside the reaction tube 203. When the seal cap 219 is elevated or lowered in the vertical direction by the boat elevator 115, the boat 217 may be transferred (loaded) into the process chamber 201 or transferred (unloaded) out of the process chamber 201.

The boat elevator 115 serves as a transfer device (which is a transfer structure or a transfer system) that loads the boat 217 and the wafers 200 accommodated in the boat 217 into the process chamber 201 or unloads the boat 217 and the wafers 200 accommodated in the boat 217 out of the process chamber 201. Further, a shutter 219s serving as a furnace opening lid capable of airtightly sealing (or closing) the lower end opening of the manifold 209 is provided under the manifold 209. The shutter 219s is configured to close the lower end opening of the manifold 209 when the seal cap 219 is lowered by the boat elevator 115. For example, the shutter 219s is made of a metal material such as SUS, and is of a disk shape. An O-ring 220c serving as a seal is provided on an upper surface of the shutter 219s so as to be in contact with the lower end of the manifold 209. An opening and closing operation of the shutter 219s such as an elevation operation and a rotation operation is controlled by a shutter opener/closer (which is a shutter opening/closing structure) 115s.

The temperature sensor 263 serving as a temperature detector is installed in the reaction tube 203. A state of electric conduction to the heater 207 is adjusted based on temperature information detected by the temperature sensor 263 such that a desired temperature distribution of an inner temperature of the process chamber 201 can be obtained. Similar to the nozzles 249a and 249b, the temperature sensor 263 is provided along the inner wall of the reaction tube 203.

### <Controller>

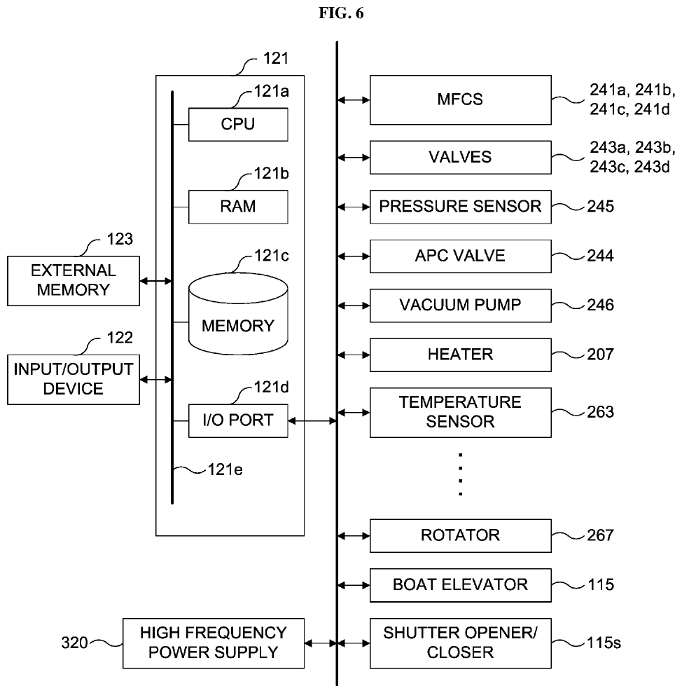

A controller 121 will be described with reference to FIG. 6. As shown in FIG. 6, the controller 121 serving as a control device (or a control structure) is constituted by a computer including a CPU (Central Processing Unit) 121a, a RAM (Random Access Memory) 121b, a memory 121c and an I/O port 121d. The RAM 121b, the memory 121c and the I/O port 121d may exchange data with the CPU 121a through an internal bus 121e. For example, an input/output device 122 constituted by a component such as a touch panel is connected to the controller 121.

For example, the memory 121c is configured by a component such as a flash memory, a hard disk drive (HDD) and a solid state drive (SSD). For example, a control program configured to control an operation of the substrate processing apparatus or a process recipe containing information on sequences and conditions of the substrate processing described later is readably stored in the memory 121c. The process recipe is obtained by combining steps of various processes such as a film-forming process described later such that the controller 121 can execute the steps to acquire a predetermined result, and functions as a program. Hereafter, the process recipe and the control program may be collectively or individually referred to as a “program”. Further, the process recipe may also be simply referred to as a “recipe.” Thus, in the present specification, the term “program” may refer to the recipe alone, may refer to the control program alone, or may refer to both of the recipe and the control program. The RAM 121b functions as a memory area (work area) where a program or data read by the CPU 121a is temporarily stored.

The I/O port 121d is connected to the above-described components such as the MFCs 241a through 241d, the valves 243a through 243d, the pressure sensor 245, the APC valve 244, the vacuum pump 246, the heater 207, the temperature sensor 263, the rotator 267, the boat elevator 115, the shutter opener/closer 115s and the high frequency power supply 320.

The CPU 121a is configured to read the control program from the memory 121c and execute the read control program. In addition, the CPU 121a is configured to read the recipe from the memory 121c in accordance with an operation command inputted from the input/output device 122. In accordance with the contents of the read recipe, the CPU 121a may be configured to control various operations such as a control operation of the rotator 267, flow rate adjusting operations for various gases by the MFCs 241a through 241d, opening and closing operations of the valves 243a through 243d, an opening and closing operation of the APC valve 244, a pressure adjusting operation by the APC valve 244 based on the pressure sensor 245, a start and stop of the vacuum pump 246, a temperature adjusting operation by the heater 207 based on the temperature sensor 263, operations of adjusting a forward rotation, a reverse rotation, a rotation angle and a rotation speed of the boat 217 by the rotator 267, an elevating and lowering operation of the boat 217 by the boat elevator 115, an opening and closing operation of the shutter 219s by the shutter opener/closer 115s and a power supply operation of the high frequency power supply 320.

The controller 121 may be embodied by installing the above-described program stored in an external memory 123 into the computer. For example, the external memory 123 may include a magnetic disk such as a hard disk, an optical disk such as a CD, a magneto-optical disk such as an MO and a semiconductor memory such as a USB memory. The memory 121c or the external memory 123 may be embodied by a non-transitory computer readable recording medium. Hereafter, the memory 121c and the external memory 123 may be collectively or individually referred to as a “recording medium”. Thus, in the present specification, the term “recording medium” may refer to the memory 121c alone, may refer to the external memory 123 alone, or may refer to both of the memory 121c and the external memory 123. Instead of the external memory 123, a communication structure such as the Internet and a dedicated line may be used for providing the program to the computer.

### (2) Substrate Processing

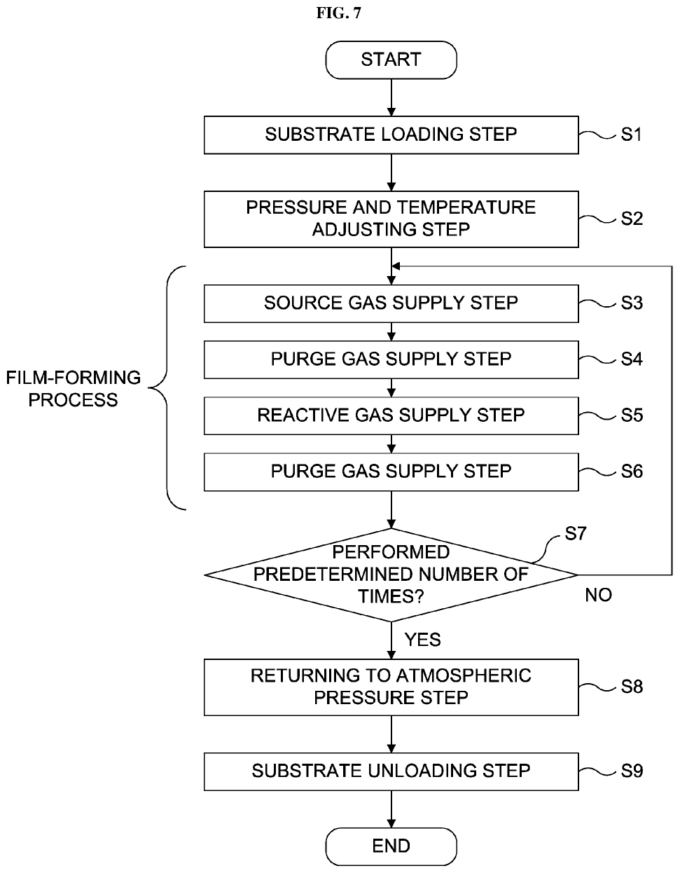

Hereinafter, an example of the substrate processing (that is, the film-forming process) of forming a film on substrates (that is, the wafers 200) by using the substrate processing apparatus described above, which is a part of a manufacturing process in a method of manufacturing the semiconductor device (substrate processing method), will be described with reference to FIG. 7. In the following descriptions, operations of components constituting the substrate processing apparatus are controlled by the controller 121.

In the present specification, a process flow of the film-forming process shown in FIG. 7 may be illustrated as follows. Film-forming processes of a modified example and other embodiments, which will be described later, will be also represented in the same manner.

(Source gas→Reactive gas)×n

In the present specification, the term “wafer” may refer to “a wafer itself,” or may refer to “a wafer and a stacked structure (aggregated structure) of a predetermined layer (or layers) or a film (or films) formed on a surface of the wafer.” In the present specification, the term “a surface of a wafer” may refer to “a surface of a wafer itself,” or may refer to “a surface of a predetermined layer (or a predetermined film) formed on a wafer.” Thus, in the present specification, “forming a predetermined layer (or a film) on a wafer” may refer to “forming a predetermined layer (or a film) directly on a surface of a wafer itself,” or may refer to “forming a predetermined layer (or a film) on a surface of another layer (or another film) formed on a wafer.” In the present specification, the terms “substrate” and “wafer” may be used as substantially the same meaning. In the present specification, the term “agent” may include at least one among a gaseous substance and a liquid substance. The liquid substance may include a mist substance. That is, an agent such as a film-forming agent, a modification agent and an etching agent may contain a gaseous substance, may contain a liquid substance such as a mist substance, or may contain both of the gaseous substance and the liquid substance.

### <Substrate Loading Step: S1>

After the wafers 200 are charged (or transferred) into the boat 217 (substrate charging step), the shutter 219s is moved by the shutter opener/closer 115s to open the lower end opening of the manifold 209 (shutter opening step). Then, as shown in FIG. 1, the boat 217 charged with the wafers 200 is elevated by the boat elevator 115 and loaded (or transferred) into the process chamber 201 (boat loading step). With the boat 217 loaded, the seal cap 219 seals the lower end of the manifold 209 via the O-ring 220b.

### <Pressure and Temperature Adjusting Step: S2>

In the present step, the vacuum pump 246 vacuum-exhausts (decompresses and exhausts) the process chamber 201 such that the inner pressure of the process chamber 201 reaches and is maintained at a desired pressure (vacuum degree). When vacuum-exhausting the process chamber 201, the inner pressure of the process chamber 201 is measured by the pressure sensor 245, and the APC valve 244 is feedback-controlled based on the pressure information measured by the pressure sensor 245 (pressure adjusting step). The vacuum pump 246 continuously vacuum-exhausts the process chamber 201 until at least a film-forming step described later is completed.

In addition, the heater 207 heats the process chamber 201 such that the inner temperature of the process chamber 201 reaches and is maintained at a desired temperature. When heating the process chamber 201, the state of electric conduction to the heater 207 is feedback-controlled based on the temperature information detected by the temperature sensor 263 such that the desired temperature distribution of the inner temperature of the process chamber 201 is obtained (temperature adjusting step). The heater 207 continuously heats the process chamber 201 until at least the film-forming step described later is completed. However, when the film-forming step is performed at a temperature equal to or lower than the room temperature, the heating of the process chamber 201 by the heater 207 may be omitted. Further, when the substrate processing including the film-forming step is performed only at the temperature equal to or lower than the room temperature, the heater 207 may be omitted and the substrate processing apparatus may be implemented without the heater 207. In such a case, it is possible to simplify the configuration of the substrate processing apparatus.

Then, the rotator 267 starts rotating the boat 217 and the wafers 200 accommodated in the boat 217. The rotator 267 continuously rotates the boat 217 and the wafers 200 accommodated in the boat 217 until at least the film-forming step described later is completed.

### <Film-Forming Step: S3, S4, S5 and S6>

Thereafter, the film-forming step is performed by performing a cycle including a source gas supply step S3, a purge gas supply step S4, a reactive gas supply step S5 and a purge gas supply step S6.

### <Source Gas Supply Step S3 and Purge Gas Supply Step S4>

In the source gas supply step S3, the source gas is supplied onto the wafers 200 in the process chamber 201.

The valve 243a is opened to supply the source gas into the gas supply pipe 232a. After a flow rate of the source gas is adjusted by the MFC 241a, the source gas whose flow rate is adjusted is supplied into the process chamber 201 through the nozzle 249a and the gas supply holes 250a, and is exhausted through the exhaust pipe 231. Thereby, the source gas is supplied onto the wafers 200. Simultaneously, the valve 243c may be opened to supply the inert gas into the gas supply pipe 232c. After a flow rate of the inert gas is adjusted by the MFC 241c, the inert gas whose flow rate is adjusted is supplied together with the source gas into the process chamber 201, and is exhausted through the exhaust pipe 231.

In order to prevent the source gas from entering the nozzle 249b, the valve 243d may be opened to supply the inert gas into the gas supply pipe 232d. The inert gas is supplied into the process chamber 201 through the gas supply pipe 232d and the nozzle 249b, and is exhausted through the exhaust pipe 231.

For example, process conditions of the present step are as follows:
A process temperature: from the room temperature (25° C.) to 550° C., preferably from 400° C. to 500° C.;
A process pressure: from 1 Pa to 4,000 Pa, preferably from 100 Pa to 1,000 Pa;
A supply flow rate of the source gas: from 0.1 slm to 3 slm;
A supply time (time duration) of supplying the source gas: from 1 second to 100 seconds, preferably from 1 second to 50 seconds; and
A supply flow rate of the inert gas (for each gas supply pipe): from 0 slm to 10 slm.

Further, in the present specification, a notation of a numerical range such as “from 25° C. to 550° C.” means that a lower limit and an upper limit are included in the numerical range. Therefore, for example, a numerical range “from 25° C. to 550° C.” means a range equal to or higher than 25° C. and equal to or lower than 550° C. The same also applies to other numerical ranges described herein. For example, in the present specification, the process temperature refers to a temperature of the wafer 200 or the inner temperature of the process chamber 201, and the process pressure refers to the inner pressure of the process chamber 201. Further, when the supply flow rate of the gas is 0 slm, it means a case where the gas is not supplied. The same also applies to the following description.

By supplying the source gas onto the wafer 200 under the above-described process conditions, a first layer is formed on the wafer 200 (that is, on a base film formed on the surface of the wafer 200). For example, when a silicon (Si)-containing gas described later is used as the source gas, a silicon-containing layer is formed on the wafer 200 as the first layer.

After the first layer is formed in the step S3, the valve 243a is closed to stop a supply of the source gas into the process chamber 201. With the APC valve 244 open, the vacuum pump 246 vacuum-exhausts the inner atmosphere of the process chamber 201 to remove a residual gas remaining in the process chamber 201 such as the source gas which did not react or which contributed to a formation of the first layer and reaction by-products from the process chamber 201 (step S4). By opening the valves 243c and 243d, the inert gas is supplied into the process chamber 201. The inert gas serves as a purge gas.

For example, an aminosilane-based gas such as tetrakis (dimethylamino) silane (Si[N(CH₃)₂]₄, abbreviated as 4DMAS) gas, tris (dimethylamino) silane (Si[N(CH₃)₂]₃H, abbreviated as 3DMAS) gas, bis (dimethylamino) silane (Si[N(CH₃)₂]₂H₂, abbreviated as BDMAS) gas, bis (diethylamino) silane (Si[N(C₂H₅)₂]₂H₂, abbreviated as BDEAS) gas, bis (tertiarybutylamino) silane (SiH₂[NH(C₄H₉)]₂, abbreviated as BTBAS) gas and (diisopropylamino) silane (SiH₃[N(C₃H₇)₂], abbreviated as DIPAS) gas may be used as the source gas. For example, one or more of the gases exemplified above as the aminosilane-based gas may be used as the source gas.

For example, a chlorosilane-based gas such as monochlorosilane (SiH₃Cl, abbreviated as MCS) gas, dichlorosilane (SiH₂Cl₂, abbreviated as DCS) gas, trichlorosilane (SiHCl₃, abbreviated as TCS) gas, tetrachlorosilane (SiCl₄, abbreviated as STC) gas, hexachlorodisilane (Si₂Cl₆, abbreviated as HCDS) gas and octachlorotrisilane (Si₃Cl₈, abbreviated as OCTS) gas may be used as the source gas. Further, for example, a fluorosilane-based gas such as tetrafluorosilane (SiF₄) gas and difluorosilane (SiH₂F₂) gas, a bromosilane-based gas such as tetrabromosilane (SiBr₄) gas and dibromosilane (SiH₂Br₂) gas, or an iodine silane-based gas such as tetraiodide silane (SiI₄) gas and diiodosilane (SiH₂I₂) gas may be used as the source gas. That is, a halosilane-based gas may be used as the source gas. For example, one or more of the gases exemplified above as the halosilane-based gas may be used as the source gas.

For example, a silicon hydride gas such as monosilane (SiH₄, abbreviated as MS) gas, disilane (Si₂H₆, abbreviated as DS) gas and trisilane (Si₃H₈, abbreviated as TS) gas may be used as the source gas. For example, one or more of the gases exemplified above as the silicon hydride gas may be used as the source gas.

For example, a nitrogen (N₂) gas or a rare gas such as argon (Ar) gas, helium (He) gas, neon (Ne) gas and xenon (Xe) gas may be used as the inert gas. The same also applies to each step described later.

### <Reactive Gas Supply Step S5 and Purge Gas Supply Step S6>

After the step S4 is completed, as the reactive gas, for example, oxygen (O₂) gas excited by the plasma is supplied onto the wafers 200 in the process chamber 201 (step S5).

In the present step, the opening and the closing of the valves 243b, 243c and 243d can be controlled in the same manners as those of the valves 243a, 243c and 243d in the source gas supply step S3. After a flow rate of the reactive gas is adjusted by the MFC 241b, the reactive gas whose flow rate is adjusted is supplied into the process chamber 201 through the nozzle 249b and the gas supply holes 250b. When supplying the reactive gas, the high frequency power (RF power) (in the present embodiment, the frequency of the high frequency power is set to 27.12 MHz) is supplied (or applied) to the electrode 300 from the high frequency power supply 320. The reactive gas supplied into the process chamber 201 is excited into the plasma state in the process chamber 201, is supplied onto the wafers 200 as the active species, and is exhausted through the exhaust pipe 231.

For example, process conditions of the present step are as follows:
A process temperature: from the room temperature (25° C.) to 550° C., preferably from 400° C. to 500° C.;
A process pressure: from 1 Pa to 300 Pa, preferably from 10 Pa to 100 Pa;
A supply flow rate of the reactive gas: from 0.1 slm to 10 slm;
A supply time (time duration) of supplying the reactive gas: from 1 second to 100 seconds, preferably from 1 second to 50 seconds;
A supply flow rate of the inert gas (for each gas supply pipe): from 0 slm to 10 slm;
The RF power: from 50 W to 1,000 W; and
The frequency of the RF power: from 25 MH to 35 MHz.

By supplying the reactive gas (which is excited into the plasma state) onto the wafer 200 under the above-described process conditions, the first layer formed on the surface of the wafer 200 is modified by the action between ions generated in the plasma and the active species which is electrically neutral. Thereby, the first layer is modified into a second layer.

For example, when an oxidizing gas (oxidizing agent) such as an oxygen-containing gas is used as the reactive gas, by exciting the oxygen-containing gas into the plasma state, an oxygen-containing active species is generated. Then, the oxygen-containing active species is supplied onto the wafer 200. In such a case, the first layer formed on the surface of the wafer 200 is oxidized by the action of the oxygen-containing active species as an oxidation process (modification process). In such a case, for example, when the first layer is the silicon-containing layer, the silicon-containing layer serving as the first layer is modified into a silicon oxide layer (also simply referred to as a “SiO layer”) serving as the second layer.

For example, when a nitriding gas (nitriding agent) such as a gas containing nitrogen (N) and hydrogen (H) is used as the reactive gas, by exciting the gas containing nitrogen and hydrogen into the plasma state, an active species containing nitrogen and hydrogen is generated. Then, the active species containing nitrogen and hydrogen is supplied onto the wafer 200. In such a case, the first layer formed on the surface of the wafer 200 is nitrided by the action of the active species containing nitrogen and hydrogen as a nitridation process (modification process). In such a case, for example, when the first layer is the silicon-containing layer, the silicon-containing layer serving as the first layer is modified into a silicon nitride layer (also simply referred to as a “SiN layer”) serving as the second layer.

After the first layer is modified into the second layer, the valve 243b is closed to stop a supply of the reactive gas into the process chamber 201. Further, the RF power supplied to the electrode 300 is also stopped. In the purge gas supply step S6, a residual gas remaining in the process chamber 201 such as the reactive gas and reaction by-products in the process chamber 201 is removed from the process chamber 201 according to the same sequence and conditions as those of the purge gas supply step S4.

For example, as described above, the oxygen-containing gas or the gas containing nitrogen (N) and hydrogen (H) may be used as the reactive gas. For example, a gas such as oxygen (O₂) gas, nitrous oxide (N₂O) gas, nitrogen monoxide (NO) gas, nitrogen dioxide (NO₂) gas, ozone (O₃) gas, hydrogen peroxide (H₂O₂) gas, water vapor (H₂O), ammonium hydroxide (NH₄(OH)) gas, carbon monoxide (CO) gas and carbon dioxide (CO₂) gas may be used as the oxygen-containing gas. For example, a hydrogen nitride gas such as ammonia (NH₃) gas, diazene (N₂H₂) gas, hydrazine (N₂H₄) gas and N₃H₈ gas may be used as the gas containing nitrogen and hydrogen. For example, one or more of the gases exemplified above as the oxygen-containing gas or the gas containing nitrogen and hydrogen may be used as the reactive gas.

For example, various gases exemplified in the step S4 may be used as the inert gas.

### <Performing Predetermined Number of Times: S7>

By performing the cycle wherein the steps S3, S4, S5 and S6 described above are performed non-simultaneously (that is, in a non-overlapping manner) in this order a predetermined number of times (n times, wherein n is an integer equal to or greater than 1) (that is, at least once), a film of a predetermined composition and a predetermined thickness is formed on the wafer 200. It is preferable that the cycle is repeatedly performed a plurality of times. That is, it is preferable that the cycle is repeatedly performed a plurality of times until a thickness of a stacked layer constituted by the first layer and the second layer reaches a desired thickness while a thickness of the first layer formed per each cycle is smaller than the desired thickness. For example, when forming the silicon-containing layer as the first layer and the SiO layer as the second layer, a silicon oxide film (also simply referred to as a “SiO film”) is formed as the film. Further, for example, when forming the silicon-containing layer as the first layer and the SiN layer as the second layer, a silicon nitride film (also simply referred to as a “SiN film”) is formed as the film.

### <Returning to Atmospheric Pressure Step: S8>

After the film-forming step described above is completed, the inert gas is supplied into the process chamber 201 through each of the gas supply pipes 232c and 232d, and then is exhausted through the exhaust pipe 231. The process chamber 201 is thereby purged with the inert gas such that the residual reactive gas or the reaction by-products remaining in the process chamber 201 are removed from the process chamber 201 (purging by the inert gas). Thereafter, the inner atmosphere of the process chamber 201 is replaced with the inert gas (substitution by the inert gas), and the inner pressure of the process chamber 201 is returned to the atmospheric pressure (returning to atmospheric pressure step S8).

### <Substrate Unloading Step: S9>

Then, the seal cap 219 is lowered by the boat elevator 115 and the lower end of the manifold 209 is opened. The boat 217 with the wafers 200 processed as described above and charged therein is transferred (or unloaded) out of the reaction tube 203 through the lower end of the manifold 209 (boat unloading step). After the boat 217 is unloaded, the shutter 219s is moved. Thereby, the lower end opening of the manifold 209 is sealed by the shutter 219s through the O-ring 220c (shutter closing step). The wafers 200 processed as described above are taken out of the reaction tube 203, and then discharged from the boat 217 (wafer discharging step). Further, an empty boat 217 may be loaded into the process chamber 201 after the wafer discharging step is performed.

In the present embodiment, the inner pressure of the furnace (that is, the process furnace 202) when the substrate processing is performed may be preferably controlled within the range of 10 Pa or more and 300 Pa or less. When the inner pressure of the furnace is lower than 10 Pa, the mean free path of the gas molecules becomes longer than the Debye length of the plasma, and the plasma directly hitting the wall of the furnace becomes noticeable. As a result, it is difficult to suppress the generation of the particles. Further, when the inner pressure of the furnace is higher than 300 Pa, the efficiency of generating the plasma is saturated so that the amount of the plasma generated does not change even when the reactive gas is supplied. Thereby, the reactive gas may be wasted. In addition, since the mean free path of the gas molecules is shortened, the transport efficiency of the active species of the plasma to the wafers 200 may deteriorate.

### (3) Effects According to Present Embodiment

By adjusting the inductance of the variable inductor 336 by the variable inductance regulator 340 while adjusting the tightening amount of the connecting screw 347 of the movable connector 334, it is possible to appropriately adjust the impedance matching position, particularly the impedance matching frequency. Therefore, when the plurality of high frequency power supplies 320 are used, the above-mentioned adjustment is performed in order to prevent the improper impedance matching in each matcher 325 due to the interferences with each other. Thereby, it is possible to make their impedance matching positions, particularly their impedance matching frequencies, be deviated from each other. Furthermore, it is possible to match the impedance matching positions, particularly the impedance matching frequencies between the plurality of semiconductor manufacturing apparatuses. Therefore, it is possible to manufacture the semiconductor device by performing the stable substrate processing by using the substrate processing apparatus capable of stably generating the plasma. As a result, it is possible to improve the yield of the semiconductor device and the quality of the semiconductor device.

### Second Embodiment

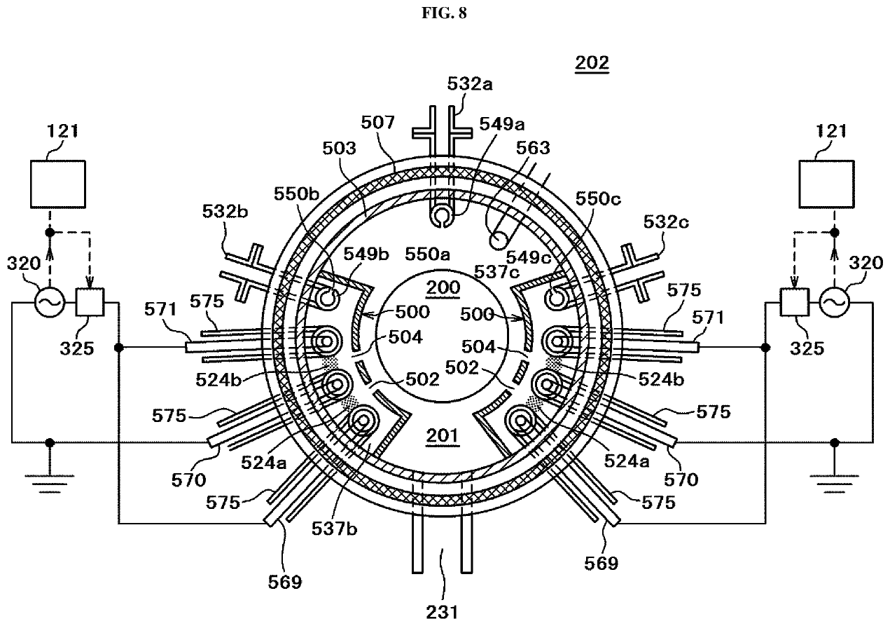

Hereinafter, a second embodiment of the present disclosure will be described mainly with reference to FIG. 8.

FIG. 8 is a diagram schematically illustrating a horizontal cross-section of a process furnace 202 of a substrate processing apparatus according to the second embodiment of the present disclosure. Similar to the first embodiment, the process furnace 202 of the second embodiment is provided with a plurality of high frequency power supplies including a high frequency power supply 320 and a plurality of matchers including a matcher 325. As the matcher 325 shown in FIG. 8, the matcher shown in FIGS. 3, 4 and 5 may be used. A plasma generator provided in the substrate processing apparatus shown in FIG. 8 will be described.

### <Plasma Generator>

As illustrated in FIG. 8, in a buffer chamber 537b, three rod-shaped electrodes 569, 570 and 571 made of a conductor and formed as an elongated thin and long structure are provided from a lower portion to an upper portion of a reaction tube 503 along the arrangement direction of the wafers 200. Each of the rod-shaped electrodes 569, 570 and 571 is provided parallel to a nozzle 549b. Each of the rod-shaped electrodes 569, 570 and 571 is covered and protected by an electrode protecting pipe 575 from an upper portion to a lower portion thereof. The two rod-shaped electrodes 569 and 571 (which are disposed at both sides of the rod-shaped electrode 570) of the three rod-shaped electrodes 569, 570 and 571 are connected to the high frequency power supply 320 through the matcher 325. The rod-shaped electrode 570 is connected to and grounded to the electrical ground serving as a reference potential. That is, the rod-shaped electrode (such as the rod-shaped electrode 569 or 571) connected to the high frequency power supply 320 and the rod-shaped electrode (such as the rod-shaped electrode 570) connected to the electrical ground are alternately arranged, and the rod-shaped electrode 570 provided between the rod-shaped electrodes 569 and 571 serves as a common ground for the rod-shaped electrodes 569 and 571. In other words, the rod-shaped electrode 570 connected to the electrical ground is disposed between the rod-shaped electrodes 569 and 571, and the rod-shaped electrodes 569 and 570 and the rod-shaped electrodes 571 and 570 respectively form pairs to generate the plasma. That is, the rod-shaped electrode 570 connected to the electrical ground is commonly used for the two rod-shaped electrodes 569 and 571 adjacent to the rod-shaped electrode 570 and connected to the high frequency power supply 320. By applying the high frequency power (RF power) to the rod-shaped electrodes 569 and 571 from the high frequency power supply 320, the plasma is generated in a plasma generation region 524a between the rod-shaped electrodes 569 and 570 and in a plasma generation region 524b between the rod-shaped electrodes 570 and 571.

Similarly, as shown in FIG. 8, in a buffer chamber 537c, three rod-shaped electrodes 569, 570 and 571 made of a conductor and formed as an elongated thin and long structure are provided from the lower portion to the upper portion of the reaction tube 503 along the arrangement direction of the wafers 200. Configurations of the three rod-shaped electrodes 569, 570, 571 provided in the buffer chamber 537c are substantially the same as those of the three rod-shaped electrodes 569, 570, 571 provided in the buffer chamber 537b described above.

A first plasma generator capable of generating the plasma in the plasma generation regions 524a and 524b is constituted mainly by the rod-shaped electrodes 569, 570 and 571 provided in the buffer chamber 537b. Similarly, a second plasma generator capable of generating the plasma in the plasma generation regions 524a and 524b is constituted mainly by the rod-shaped electrodes 569, 570 and 571 provided in the buffer chamber 537c. Each of the first plasma generator and the second plasma generator may further include the electrode protecting pipe 575. A plasma generating apparatus (also referred to as a “plasma generator”) according to the second embodiment is constituted by the high frequency power supplies 320, the matchers 325, the first plasma generator and the second plasma generator.

The plasma generating apparatus serves as a plasma activator (plasma exciter) capable of activating (or exciting) the gas into the plasma state. Further, the plasma generating apparatus includes a plurality of plasma generators as described above, and is used to perform the film-forming process by performing the substrate processing using the plasma generated by the plurality of plasma generators.

The high frequency power supply 320 supplies the electric power to each of the plurality of plasma generators. Further, the matcher 325 is provided between the high frequency power supplies 320 and the plasma generator to match a load impedance of each plasma generator and an output impedance of each high frequency power supply 320.

For example, two buffer structures (which are represented by reference numerals “500” and “500” in FIG. 8) are provided symmetrically with respect to a line passing through the exhaust pipe 231 and a center of the reaction tube 503, with the exhaust pipe 231 interposed therebetween. Further, a nozzle 549a is provided at a position facing the exhaust pipe 231 with the wafer 200 interposed therebetween. In addition, the nozzle 549b and a nozzle 549c are provided at positions far from the exhaust pipe 231 in the buffer chambers 537b and 537c, respectively.

As shown in FIG. 8, the nozzle 549a is installed in a space provided between an inner wall of the reaction tube 503 and the wafers 200, and extends upward from the lower portion toward the upper portion of the reaction tube 503 along the inner wall of the reaction tube 503 (that is, extends upward along a stacking direction of the wafers 200). That is, the nozzle 549a is installed in a region (which is located beside and horizontally surrounds the wafer arrangement region (placement region) where the wafers 200 are arranged (placed)) to extend along the wafer arrangement region. That is, the nozzle 549a is provided beside the edges (peripheries) of the wafers 200 loaded (transferred) into the process chamber 201, and are provided perpendicular to the surfaces (flat surfaces) of the wafers 200. A plurality of gas supply holes 550a through which a gas is supplied are provided at a side surface of the nozzle 549a. The gas supply holes 550a are open toward the center of the reaction tube 503, and are configured such that the gas can be supplied toward the wafers 200 through the gas supply holes 550a. The gas supply holes 550a are provided from the lower portion toward the upper portion of the reaction tube 503. An opening area of each of the gas supply holes 550a is the same, and the gas supply holes 550a are provided at the same opening pitch.

In the process furnace 202, the nozzles 549b and 549c are provided in the buffer chambers 537b and 537c serving as gas dispersion spaces, respectively. As shown in FIG. 8, each of the buffer chambers 537b and 537c is installed in an annular space provided between the inner wall of the reaction tube 503 and the wafers 200 when viewed from above, and extends upward from the lower portion toward the upper portion of the reaction tube 503 along the inner wall of the reaction tube 503 (that is, extends upward along the stacking direction of the wafers 200). That is, each of the buffer chambers 537b and 537c is provided in the region (which is located beside and horizontally surrounds the wafer arrangement region) to extend along the wafer arrangement region, and is formed by the buffer structures 500. Each of the buffer structures 500 is made of an insulating material such as quartz, and gas supply ports 502 and 504 through which the gases are supplied are provided in an arc-shaped wall of each buffer structure 500.

As shown in FIG. 8, the gas supply ports 502 and 504 are provided at positions facing the plasma generation regions 524a and 524b between the rod-shaped electrodes 569 and 570 and between the rod-shaped electrodes 570 and 571, respectively. The gas supply ports 502 and 504 are open toward the center of the reaction tube 503, and are configured such that the gases can be supplied toward the wafers 200 through the gas supply ports 502 and 504. The gas supply ports 502 and 504 are provided from the lower portion toward the upper portion of the reaction tube 503. An opening area of each of the gas supply ports 502 and 504 is the same, and the gas supply ports 502 and 504 are provided at the same opening pitch.

Each of the nozzles 549b and 549c is installed so as to extend upward from the lower portion toward the upper portion of the reaction tube 503 along the inner wall of the reaction tube 503 (that is, extends upward along the stacking direction of the wafers 200). That is, either the nozzle 549b or 549c is provided in the buffer structure 500 in the region (which is located beside and horizontally surrounds the wafer arrangement region) to extend along the wafer arrangement region.

A plurality of gas supply holes 550b are provided at a side surface of the nozzle 549b. The gas supply holes 550b are open toward a wall provided in a radial direction with respect to the arc-shaped wall of the buffer structure 500 (that is, in a circumferential direction different from an opening direction of each of the gas supply ports 502 and 504), and are configured such that the gases can be supplied toward the wall. Thereby, the reactive gas is dispersed within the buffer chamber 537b, and the reactive gas is no longer ejected directly onto the rod-shaped electrodes 569 through 571. As a result, it is possible to suppress the generation of the particles. Similar to the gas supply holes 550a, the plurality of gas supply holes 550b are provided from the lower portion toward the upper portion of the reaction tube 503. A structure of the nozzle 549c is substantially the same as that of the nozzle 549b.

As a source material containing a predetermined element, for example, a silane source gas containing silicon (Si) as the predetermined element can be supplied into the process chamber 201 through a gas supply pipe 532a via the nozzle 549a. As a reactant containing an element different from the predetermined element, for example, a nitrogen (N)-containing gas serving as the reactive gas can be supplied into the process chamber 201 through a gas supply pipe 532b via the nozzle 549b. As a modification gas, for example, hydrogen (H₂) gas can be supplied into the process chamber 201 through a gas supply pipe 532c via the nozzle 549c.

According to the second embodiment, it is possible to obtain effects similar to those of the first embodiment.

### Other Embodiments of Present Disclosure

While the technique of the present disclosure is described in detail by way of the embodiments described above, the technique of the present disclosure is not limited thereto. The technique of the present disclosure may be modified in various ways without departing from the scope thereof. Further, the embodiments described above and modified examples may be appropriately combined. In addition, process sequences and process conditions of each combination thereof may be substantially the same as those of the embodiments described above or the modified examples.

For example, the embodiments described above are described by way of an example in which the reactant (that is, the reactive gas) is supplied after the source material (that is, the source gas) is supplied. However, the technique of the present disclosure is not limited thereto. The technique of the present disclosure may also be applied when a supply order of the source gas and the reactive gas is changed. That is, the technique of the present disclosure may be applied when the source gas is supplied after the reactive gas is supplied. By changing the supply order of the gases, it is possible to change the quality or the composition of the film formed by performing the substrate processing.

For example, the embodiments described above are described by way of an example in which the silicon oxide film (SiO film) or the silicon nitride film (SiN film) is formed on the wafer 200. However, the technique of the present disclosure is not limited thereto. For example, the technique of the present disclosure may also be preferably applied to form, on the wafer 200, a silicon-based oxide film such as a silicon oxycarbide film (SiOC film), a silicon oxycarbonitride film (SiOCN film) and a silicon oxynitride film (SiON film).

It is preferable that recipes used in the film-forming process are prepared individually in accordance with process contents and stored in the memory 121c via an electric communication line or the external memory 123. When starting various processes, it is preferable that the CPU 121a selects an appropriate recipe among the recipes stored in the memory 121c in accordance with the process contents. Thus, various films of different composition ratios, qualities and thicknesses can be formed in a reproducible manner and in a universal manner by using a single substrate processing apparatus. In addition, since a burden on an operating personnel of the substrate processing apparatus can be reduced, various processes can be performed quickly while avoiding an erratic operation of the substrate processing apparatus.

The recipe described above is not limited to creating a new recipe. For example, the recipe may be prepared by changing an existing recipe stored in the substrate processing apparatus in advance. When changing the existing recipe to a new recipe, the new recipe may be installed in the substrate processing apparatus via the electric communication line or the recording medium in which the new recipe is stored. Further, the existing recipe already stored in the substrate processing apparatus may be directly changed to the new recipe by operating the input/output device 122 of the substrate processing apparatus.

For example, the embodiments described above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of simultaneously processing one or several substrates is used to form the film. For example, the embodiments described above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film. The process sequences and the process conditions of each process using the substrate processing apparatuses exemplified above may be substantially the same as those of the embodiments described above. Even in such a case, it is possible to obtain substantially the same effects as in the embodiments described above.

According to some embodiments of the present disclosure, it is possible to stabilize the generation of the plasma by avoiding the improper impedance matching.

What is claimed is:

1. A matcher comprising:
an input structure configured to receive a high frequency power;
an output structure configured to output the high frequency power;
a matching structure containing a variable inductor with a variable inductance; and
a variable inductance regulator capable of varying the inductance of the variable inductor.

2. The matcher of claim 1, wherein the variable inductor is constituted by a coil, and the inductance of the variable inductor is variable by varying a pitch of the coil.

3. The matcher of claim 2, wherein the variable inductance regulator comprises a fixture configured to fix the coil and a mover configured to vary the pitch of the coil.

4. The matcher of claim 3, wherein the mover is of a plate shape.

5. The matcher of claim 3, wherein the mover is moved by a rotation structure.

6. The matcher of claim 5, wherein the rotation structure comprises a rotating shaft configured to move the mover, a first gear configured to rotate the rotating shaft and a second gear configured to rotate the first gear.

7. The matcher of claim 6, wherein the rotating shaft comprises a threaded shape, and the mover comprises a threaded hole shape.

8. The matcher of claim 1, wherein the matching structure comprises a capacitor or a variable capacitor.

9. The matcher of claim 1, wherein the variable inductor is connected to a movable connector.

10. The matcher of claim 9, wherein the variable inductor is connected to the input structure via the movable connector.

11. The matcher of claim 10, wherein the movable connector is connected to a load matching structure.

12. The matcher of claim 9, wherein the movable connector comprises a movable structure connected to the variable inductor and a fixed structure of fixing the movable structure.

13. The matcher of claim 12, wherein the movable connector comprises a screw configured to fix the movable structure.

14. The matcher of claim 12, wherein the variable inductor is connected to the movable structure, and the movable structure is fixed and electrically connected to the fixed structure.

15. The matcher of claim 1, wherein the output structure is provided in a process chamber in which a substrate is processed, and is connected to an electrode provided in a plasma generator configured to generate a plasma.

16. The matcher of claim 15, wherein the matcher is provided between the plasma generator and a high frequency power supply configured to output the high frequency power.

17. The matcher of claim 16, wherein a plurality of high frequency power supplies comprising the high frequency power supply and a plurality of plasma generators comprising the plasma generator are provided, and the matcher is configured to be provided for each of the plasma generators and each of the high frequency power supplies by being interposed therebetween.

18. A substrate processing apparatus comprising:
a process chamber in which a substrate is processed;
an electrode configured to generate a plasma;
a high frequency power supply configured to supply a high frequency power to the electrode; and
a matcher provided between the electrode and the high frequency power supply and comprising:
an input structure configured to receive the high frequency power;
an output structure configured to output the high frequency power;
a matching structure containing a variable inductor with a variable inductance; and
a variable inductance regulator capable of varying the inductance of the variable inductor.

19. A method of manufacturing a semiconductor device, comprising:
(a) loading a substrate into a process chamber of a substrate processing apparatus, wherein the substrate processing apparatus comprises:
the process chamber in which the substrate is processed;
an electrode configured to generate a plasma;
a high frequency power supply configured to supply a high frequency power to the electrode; and
a matcher provided between the electrode and the high frequency power supply and comprising:
an input structure configured to receive the high frequency power;
an output structure configured to output the high frequency power;
a matching structure containing a variable inductor with a variable inductance; and
a variable inductance regulator capable of varying the inductance of the variable inductor; and
(b) processing the substrate.

20. A non-transitory computer-readable recording medium storing a program that causes a substrate processing apparatus, by a computer, to perform:
(a) loading a substrate into a process chamber of the substrate processing apparatus, wherein the substrate processing apparatus comprises:
the process chamber in which the substrate is processed;
an electrode configured to generate a plasma;
a high frequency power supply configured to supply a high frequency power to the electrode; and
a matcher provided between the electrode and the high frequency power supply and comprising:
an input structure configured to receive the high frequency power;
an output structure configured to output the high frequency power;
a matching structure containing a variable inductor with a variable inductance; and
a variable inductance regulator capable of varying the inductance of the variable inductor; and
(b) processing the substrate.
